(19) United States
(12) Patent Application Publication
(10) Pub. No.: US 2023/0202759 A1
(43) Pub. Date: Jun. 29, 2023

(54) TRANSFERRING APPARATUS AND TRANSFERRING METHOD

(71) Applicant: SEMES CO., LTD., Cheonan-si (KR)

(72) Inventor: Myeong Jin BANG, Seoul (KR)

(73) Assignee: SEMES CO., LTD., Cheonan-si (KR)

(21) Appl. No.: 18/146,793

(22) Filed: Dec. 27, 2022

(30) Foreign Application Priority Data
Dec. 27, 2021 (KR) 10-2021-0188997
Jun. 30, 2022 (KR) 10-2022-0080460

(51) Int. Cl. B65G 1/137

(52) U.S. Cl. CPC B65G 1/1376

(57) ABSTRACT

Provided is a transferring apparatus for transferring a container in which an article is accommodated. The transferring apparatus may include a first rail, a second rail located below the first rail, and a transfer unit located on the sides of the first rail and the second rail, and configured to transfer the container between a first vehicle traveling on the first rail and a second vehicle traveling on the second rail, in which the transfer unit may include a frame having an elevation space therein, and an elevation member for elevating the container between a first position transferring the first vehicle and the container and a second position transferring the second vehicle and the container, in the elevation space.

### CROSS-REFERENCE TO RELATED APPLICATIONS

This application claims priority to and the benefit of the Korean Patent Application No. 10-2021-0188997 filed on Dec. 27, 2021 and Korean Patent Application No. 10-2022-0080460 filed on Jun. 30, 2022, in the Korean Intellectual Property Office, the entire contents of each of which are herein incorporated by reference.

### TECHNICAL FIELD

The present invention relates to a transferring apparatus and a transferring method, and more particularly, to an apparatus and a method for transferring an article used in a semiconductor device manufacturing process.

### BACKGROUND ART

In general, in order to manufacture a semiconductor, various types of processes such as deposition, photolithography, and etching are performed. Semiconductor processing devices performing respective processes are disposed in a semiconductor manufacturing line. The semiconductor manufacturing line may have a multi-layered structure. A substrate (e.g., wafer, glass), which is an article used in the semiconductor manufacturing process, may be transferred to each semiconductor processing device while being accommodated in a container such as a FOUP. In addition, in the semiconductor manufacturing process, the article on which a predetermined process has been completed is recovered from the semiconductor processing device to the container, and the recovered container is transferred to the outside.

The container is transferred by a vehicle such as an overhead hoist transport. A transfer vehicle travels along rails provided in the semiconductor manufacturing line. The vehicle transfers a container in which the article is accommodated to a load port of one of the semiconductor processing devices. In addition, the vehicle may pick up the container in which the article on which the predetermined process has been completed is accommodated from the load port and transfer the container to the outside or transfer the container to the other one of the semiconductor processing devices.

In order to improve the processing efficiency of manufacturing the semiconductor disposed on any one floor of the semiconductor manufacturing line, it is necessary to shorten the time when the vehicle transfers the container between semiconductor processing devices. As a method for shortening the container transfer time of the vehicle, a method of separately using the rails on which the vehicle travels has been used. An upper rail and a lower rail disposed below the upper rail having different uses are provided on the ceiling of the semiconductor manufacturing line. For example, the upper rail may be used as a high-speed traveling path of the vehicle, and the lower rail may be used as a low-speed traveling path of the vehicle. As described above, when the uses of the upper rail and the lower rail are different to shorten the container transfer time of the vehicle, it is necessary to exchange the container between the vehicle traveling on the upper rail and the vehicle traveling on the lower rail.

In order to directly move the vehicle between the upper rail and the lower rail, it is necessary to provide a slope rail for connecting the upper rail and the lower rail to each other. The slope rail causes a structural problem that consumes a space within the semiconductor manufacturing line. In addition, when exchanging the container between the upper rail and the lower rail using the slope rail, congestion occurs in the slope rail section according to the number of vehicles traveling in the slope rail section. This congestion leads to a result of rather lowering the semiconductor manufacturing efficiency.

### SUMMARY OF THE INVENTION

An object of the present invention is to provide a transferring apparatus and a transferring method capable of efficiently transferring articles to be used in a semiconductor manufacturing line.

Another object of the present invention is to provide a transferring apparatus and a transferring method capable of efficiently exchanging articles between vehicles traveling on rails with different uses.

Yet another object of the present invention is to provide a transferring apparatus and a transferring method capable of efficiently exchanging articles between vehicles traveling on different rails provided on the same floor of a semiconductor manufacturing line in which semiconductor devices are continuously disposed.

Other objects of the present invention are not limited thereto, and other objects, which are not mentioned above, will be apparent to those skilled in the art from the following description.

An embodiment of the present invention provides a transferring apparatus for transferring a container in which an article is accommodated. The transferring apparatus may include a first rail, a second rail located below the first rail, and a transfer unit located on the sides of the first rail and the second rail, and configured to transfer the container between a first vehicle traveling on the first rail and a second vehicle traveling on the second rail, in which the transfer unit may include a frame having an elevation space therein, and an elevation member for elevating the container between a first position transferring the first vehicle and the container and a second position transferring the second vehicle and the container, in the elevation space.

According to an embodiment, the transferring apparatus may be disposed above a plurality of semiconductor devices, a semiconductor manufacturing line in which the plurality of the semiconductor devices are continuously disposed may be formed of at least one floor, and the first rail, the second rail, and the transfer unit may be disposed on the same layer of the semiconductor manufacturing line.

According to an embodiment, the second vehicle may travel on the second rail at a speed lower than that of the first vehicle to transfer the semiconductor device and the container.

According to an embodiment, the first rail and the frame may be fixed to a ceiling of the semiconductor manufacturing line, and the second rail may be fixed via the first rail.

According to an embodiment, the transfer unit may include a first transfer unit located on one side of the first rail; and a second transfer unit located on the other side facing one side of the first rail based on the first rail.

According to an embodiment, the first transfer unit may include a first frame and a first elevation member, in which the first elevation member may include an elevation plate for supporting a lower surface of the container; and a first driving member provided on a lower wall of the first frame and moving the elevation plate in a vertical direction, and the second transfer unit may include a second frame and a second elevation member, in which the second elevation member may include a grip member for gripping a flange formed at an upper portion of the container; and a second driving member provided on an upper wall of the second frame and moving the grip member in a vertical direction.

According to an embodiment, the first vehicle may travel only on the first rail of the first rail and the second rail, and the second vehicle may travel only on the second rail of the first rail and the second rail.

According to an embodiment, the transfer unit may further include a support member for transferring the first vehicle, the elevation member, and the container in the elevation space.

According to an embodiment, the support member may be provided at the first position.

According to an embodiment, the support member may be provided on the frame and may slide between a support position capable of supporting the container in the elevation space and a stand-by position which does not interfere with the container elevating in the elevation space.

According to an embodiment, the support member may not interfere with the elevation member when the elevation member moves up and down in the elevation space.

According to an embodiment, each of the first vehicle and the second vehicle comprises a slider that changes the position of the container laterally with respect to a traveling direction, among side surfaces of the frame, the side surfaces facing the first rail and the second rail are opened, and the slider moves the container to the elevation space through the opened side surfaces.

According to an embodiment, the transferring apparatus may further include a controller, in which the controller may control the support member, the slider, and the elevation member so as to seat the container on the support member by moving the slider to the elevation space after slidably moving the support member to the support position when moving the container from the first vehicle to the elevation space, to elevate the elevation member to the first position so that the elevation member supports the container after the container is seated on the support member, and to slidably move the support member to the stand-by position after the elevation member supports the container.

According to an embodiment, the transferring apparatus may further include a controller, in which the controller may control the support member, the slider, and the elevation member so that the elevation member slidably moves the support member to the stand-by position before elevating the container to the first position when moving the container to the first vehicle in the elevation space, the elevation member elevates the container to the first position when the support member moves to the stand-by position, and the elevation member slidably moves the support member to the support position when the elevation member is located at the first position.

Another embodiment of the present invention provides a transferring method of transferring a container in which an article is accommodated along a first rail in the same layer of a semiconductor manufacturing line in which semiconductor devices are continuously disposed and a second rail disposed at a different height from the first rail. The transferring method may include exchanging the container between a first vehicle traveling on the first rail and a second vehicle traveling on the second rail in an elevation space in a frame located at a side with respect to a longitudinal direction of the first rail and the second rail, and elevating the container between a first position transferring the first vehicle and the container and a second position transferring the second vehicle and the container, by an elevation member provided in the elevation space.

According to an embodiment, the support member provided at the first position transfers the first vehicle, the elevation member, and the container, in which the support member slides between a support position capable of supporting the container in the elevation space and a stand-by position which does not interfere with the container elevating in the elevation space.

According to an embodiment, the transferring method may further include moving the container supported by the first vehicle onto the support member after slidably moving the support member to the support position when moving the container from the first vehicle to the elevation space.

According to an embodiment, the elevation member may elevate the support member to the first position so as to support the container seated on the support member and the elevation member may slidably move the support member to the stand-by position after supporting the container.

According to an embodiment, the elevation member may slidably move the support member to the stand-by position before elevating the container to the first position when moving the container to the first vehicle in the elevation space, the elevation member may elevate the container to the first position when the support member moves to the stand-by position, the elevation member may slidably move the support member to the support position when the elevation member is located at the first position, and the first vehicle may transfer the container seated on the support member to the outside of the elevation space.

Yet another embodiment of the present invention provides a transferring apparatus for transferring a container in which an article is accommodated in the same layer of a semiconductor manufacturing line in which semiconductor devices are continuously disposed. The transferring apparatus may include a first vehicle traveling on a fist rail to transfer the container; a second vehicle traveling on a second rail located below the first rail to transfer the container; and a plurality of transfer units located sides of the first rail and the second rail to transfer the container between the first vehicle and the second vehicle, in which the first vehicle includes a first slider for changing the position of the container while being transferring by the first vehicle laterally with respect to the traveling direction of the first vehicle, and the second vehicle includes a second slider for changing the position of the container while being transferring by the second vehicle laterally with respect to the traveling direction of the second vehicle, and in which the transfer unit may include a frame having an elevation space therein; and an elevation member for elevating the container between a first position transferring the first vehicle and the container and a second position transferring the second vehicle and the container.

According to the embodiment of the present invention, it is possible to efficiently transfer articles used in a semiconductor manufacturing line.

In addition, according to the embodiment of the present invention, it is possible to efficiently exchange articles between vehicles traveling on rails with different uses.

In addition, according to the embodiment of the present invention, it is possible to efficiently exchange articles between vehicles traveling on different rails provided on the same floor of a semiconductor manufacturing line in which semiconductor devices are continuously disposed.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram schematically illustrating an appearance of a semiconductor manufacturing line according to an embodiment when viewed from the front.

FIG. 2 is a diagram schematically illustrating an appearance of the semiconductor manufacturing line according to the embodiment of FIG. 1 when viewed from the top.

FIG. 3 is a diagram illustrating a transferring apparatus according to an embodiment of FIG. 1 when viewed from the front.

FIG. 4 is a diagram illustrating a state in which a first vehicle travels on a first rail according to an embodiment of FIG. 3 when viewed from the front.

FIG. 5 is a diagram illustrating a state in which the first vehicle travels on the first rail according to an embodiment of FIG. 3 when viewed from the side.

FIG. 6 is a perspective view of a transfer unit according to an embodiment of FIG. 3.

FIGS. 7 to 11 are diagrams sequentially illustrating a state of exchanging a container in the transferring apparatus according to an embodiment of FIG. 3.

FIG. 12 is a diagram illustrating a transfer unit according to another embodiment of FIG. 3 when viewed from the front.

FIG. 13 is a perspective view of the transfer unit according to another embodiment of FIG. 12.

FIG. 14 is a diagram schematically illustrating the transfer unit when viewed from the top, when a support plate of FIG. 12 is located at a support position.

FIG. 15 is a diagram schematically illustrating the transfer unit when viewed from the top, when the support plate of FIG. 12 is located at a stand-by position.

FIGS. 16 to 18 are perspective views sequentially illustrating a state in which the container is transferred in an elevation space of the transfer unit according to an embodiment of FIG. 12.

FIGS. 19 and 20 are diagrams illustrating the transfer unit according to another embodiment of FIG. 12 when viewed from the front.

### DETAILED DESCRIPTION

Hereinafter, embodiments of the present invention will be described in more detail with reference to the accompanying drawings. Embodiments of the present invention may be modified in various forms and should not be construed that the scope of the present invention is limited to embodiments to be described below. The embodiments will be provided for more completely explaining the present invention to those skilled in the art. Therefore, shapes, and the like of components in the drawings are exaggerated to emphasize a more clear description.

Terms, such as first and second, are used for describing various constituent elements, but the constituent elements are not limited by the terms. The terms are used only for distinguishing one component from the other component. For example, without departing from the scope of the invention, a first constituent element may be named as a second constituent element, and similarly a second constituent element may be named as a first constituent element.

A transferring apparatus and a transferring method according to an embodiment of the present invention may be used to transfer a container. In particular, the transferring apparatus and method according to an embodiment of the present invention may transfer the container in which an article is accommodated. According to an embodiment, the article may include a substrate such as a wafer or reticle. The container in which the article is accommodated may include a front opening unified pod (FOUP) or a cassette. In addition, the container in which the article is accommodated may include a pod. In addition, the container in which the article is accommodated may include a magazine for accommodating a plurality of printed circuit boards, a tray for accommodating a plurality of semiconductor packages, and the like.

Hereinafter, the transferring apparatus and the transferring method according to an embodiment of the present invention will be described as an example in which a container in which a substrate such as a wafer is accommodated is transferred to semiconductor devices disposed in a semiconductor manufacturing line. In addition, the article transferred by an article transfer device (hereinafter, a vehicle) will be described with a substrate used for semiconductor manufacturing as an example. However, the present invention is not limited thereto, and the vehicle according to an embodiment of the present invention may be equally or similarly applied to various semiconductor manufacturing lines requiring the transferring of an article and/or a container in which the article is accommodated.

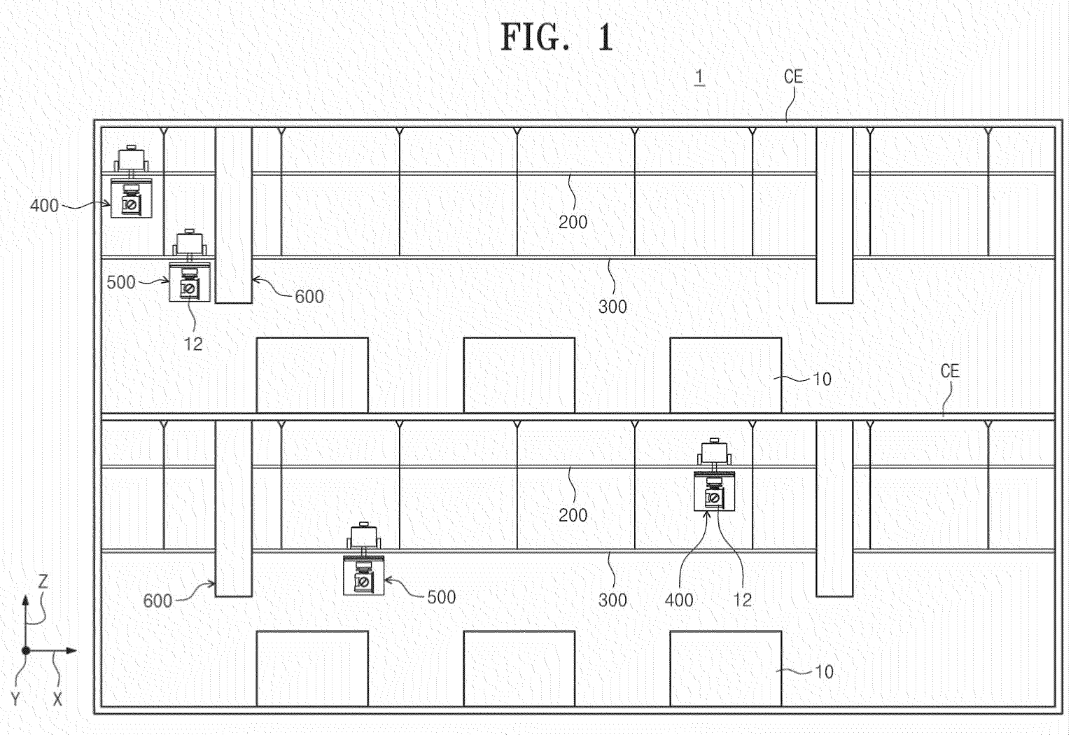

Hereinafter, an embodiment of the present invention will be described in detail with reference to FIGS. 1 to 20.

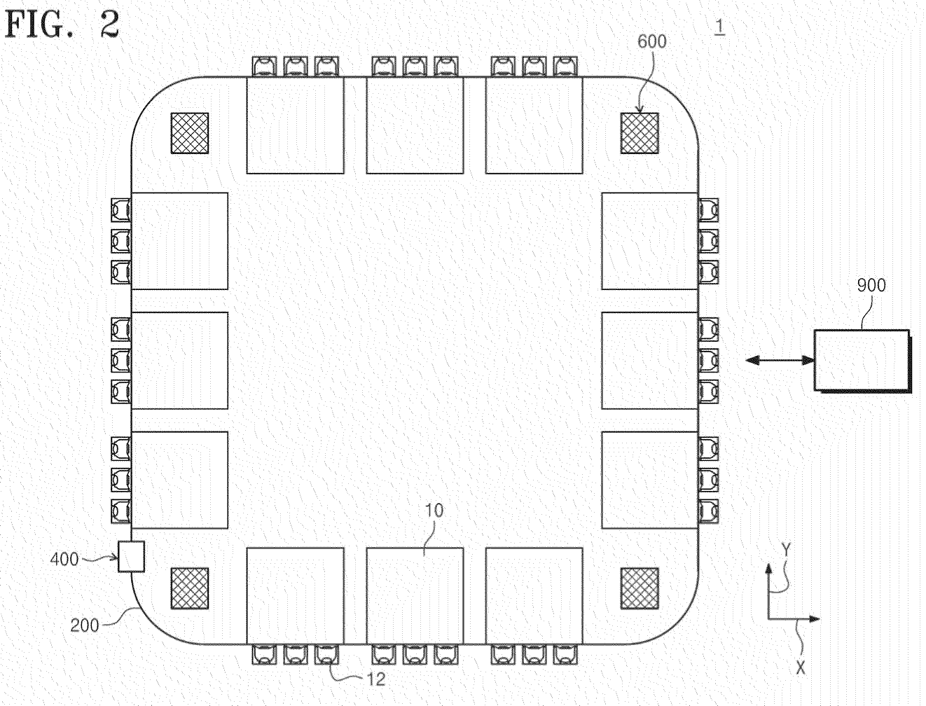

FIG. 1 is a diagram schematically illustrating an appearance of a semiconductor manufacturing line according to an embodiment when viewed from the front. FIG. 2 is a diagram schematically illustrating an appearance of the semiconductor manufacturing line according to the embodiment of FIG. 1 when viewed from the top.

Referring to FIGS. 1 and 2, a semiconductor manufacturing line 1 of the present invention may include at least one or more floors. For example, the semiconductor manufacturing line 1 may have a multi-floor structure. As illustrated in FIG. 1, the semiconductor manufacturing line 1 may have a two-floor structure. However, this is for convenience of description, and the semiconductor manufacturing line 1 may have a multi-floor structure in which three or more (a natural number) floors are stacked.

Semiconductor devices 10 may be sequentially disposed on each floor of the semiconductor manufacturing line 1. The semiconductor devices 10 may be located at a lower portion of the semiconductor manufacturing line 1. The semiconductor devices 10 may perform a deposition process, a photolithography process, or an etching process on the substrate. However, it is not limited to the above-described example, and the semiconductor devices 10 may perform various processes on the substrate.

Hereinafter, when the semiconductor manufacturing line 1 is viewed from the front, a direction in which the semiconductor devices 10 are arranged is defined as a first direction X. In addition, a direction perpendicular to the first direction X on a horizontal plane is defined as a second direction Y. In addition, a direction perpendicular to a plane including both the first direction X and the second direction Y is defined as a third direction Z. According to an embodiment, the third direction Z may be a direction perpendicular to the ground.

A transfer device 20 may be disposed on the semiconductor manufacturing line 1. The transfer device 20 according to an embodiment of the present invention is disposed on each floor of the semiconductor manufacturing line 1. The transfer device 20 may transfer a container 12 in which the article is accommodated in the semiconductor manufacturing line 1. Specifically, the transfer device 20 may transfer the container 12 in which the article is accommodated in the semiconductor manufacturing line 1 in which the semiconductor devices 10 are continuously disposed. The transfer device 20 may be located at an upper portion of the semiconductor manufacturing line 1. Also, the transfer device 20 may be located above the semiconductor devices 10.

The transfer device 20 may include a first rail 200, a second rail 300, a first vehicle 400, a second vehicle 500, a transfer unit 600, and a controller 900.

The first rail 200 functions as a path on which the first vehicle 400 to be described below travels. The first rail 200 is located at the upper portion of the semiconductor manufacturing line 1. In addition, the first rail 200 may be located above the second rail 300 to be described below. According to an embodiment, the first rail 200 may be a high-speed traveling rail. For example, the traveling speed of the first vehicle 400 traveling on the first rail 200 may be faster than the traveling speed of the second vehicle 500 traveling on the second rail 300. As illustrated in FIG. 2, the first rail 200 may include a rail having a straight structure and a rail having a curved structure. Although not illustrated, the first rail 200 may further include a branched rail.

In FIG. 2, the first rail 200 is illustrated in a substantially rectangular shape, but the shape of the first rail 200 may be modified into various shapes such as a circular shape and a hexagonal shape. The first rail 200 may be provided along the ceiling of the semiconductor manufacturing line 1 to view the semiconductor devices 10 from the upper side. In addition, the first rail 200 may have an installation range capable of covering the entire semiconductor devices 10.

The second rail 300 functions as a path on which the second vehicle 500 to be described below travels. The second rail 300 is located at the upper portion of the semiconductor manufacturing line 1. In addition, the second rail 300 may be located below the first rail 200. According to an embodiment, the second rail 300 may be a low-speed traveling rail. For example, the traveling speed of the second vehicle 500 traveling on the second rail 300 may be lower than the traveling speed of the first vehicle 400 traveling on the first rail 200. Although not illustrated, the second rail 300 may include a rail having a straight structure, a rail having a curved structure, and a branched rail, similar to the first rail 200. In addition, when viewed from the top, the second rail 300 may have a similar installation range to a structure similar to that of the first rail 200.

In addition, according to an embodiment of the present invention, the first rail 200 and the second rail 300 may not be connected to each other. For example, a rail having a slope structure connecting the first rail 200 and the second rail 300 to each other may not be provided. Accordingly, the first vehicle 400 traveling on the first rail 200 can travel only on the first rail 200, and the second vehicle 500 traveling on the second rail 300 can travel only on the second rail 300.

The first vehicle 400 travels along the first rail 200. The first vehicle 400 may hold the container 12. The first vehicle 400 transfers the container 12 along the first rail 200. According to an embodiment, the first vehicle 400 may be an overhead hoist vehicle.

The second vehicle 500 travels along the second rail 300. The second vehicle 500 may hold the container 12. The second vehicle 500 transfers the container 12 along the second rail 300. According to an embodiment, the second vehicle 500 may be an overhead hoist vehicle.

At least one or more transfer units 600 may be included. The transfer unit 600 may be disposed on each floor of the semiconductor manufacturing line 1. The transfer unit 600 may be located at the upper portion of the semiconductor manufacturing line 1. The transfer unit 600 transfers the container 12 between the first vehicle 400 and the second vehicle 500. According to an embodiment, the transfer unit 600 may transfer the container 12 which is being transferred by the first vehicle 400 to the second vehicle 500. In addition, the transfer unit 600 may transfer the container 12 which is being transferred by the second vehicle 500 to the first vehicle 400. In addition, the transfer unit 600 may temporarily store the container 12 transferred to or from the semiconductor device 10.

The controller 900 may control the transfer device 20. The controller 900 may control the transfer device 20 to transfer the container 12 in which the article is accommodated to or from the semiconductor device 10. In addition, the controller 900 may control the transfer device 20 so as to transfer the container 12 to the transfer unit 600 or from the transfer unit 600. Specifically, the controller 900 may control a slider, an elevation member, and a support member, which will be described below.

The controller 900 may include a process controller consisting of a microprocessor (computer) executing a control of the transfer device 20, a keyboard for performing a command input operation and the like to manage the transfer device 20 by an operator, a user interface consisting of a display and the like for visualizing and displaying an moving situation of the transfer device 20, and a memory unit stored with a treatment recipe including control programs for executing the treatment executed in the transfer device 20 under the control of the process controller, or programs for executing the treatment in each component according to various data and treatment conditions. In addition, the user interface and the memory unit may be connected to the process controller. The treatment recipe may be stored in a storage medium of the memory unit. The storage medium may include a hard disk, a portable disk such as a CD-ROM or a DVD, or a semiconductor memory such as a flash memory.

Hereinafter, a transferring apparatus according to an embodiment of the present invention will be described in detail. The transferring apparatus according to an embodiment to be described below may be an apparatus disposed on any one floor of the semiconductor manufacturing line 1 illustrated in FIG. 1. For the convenience of understanding, the transferring apparatus disposed on any one floor of the semiconductor manufacturing line 1 is just described, and the structure and the operation of the transfer device 20 disposed on different floors of the semiconductor manufacturing line 1 having a multi-floor structure are also the same as or similar to those of a transferring apparatus to be described below.

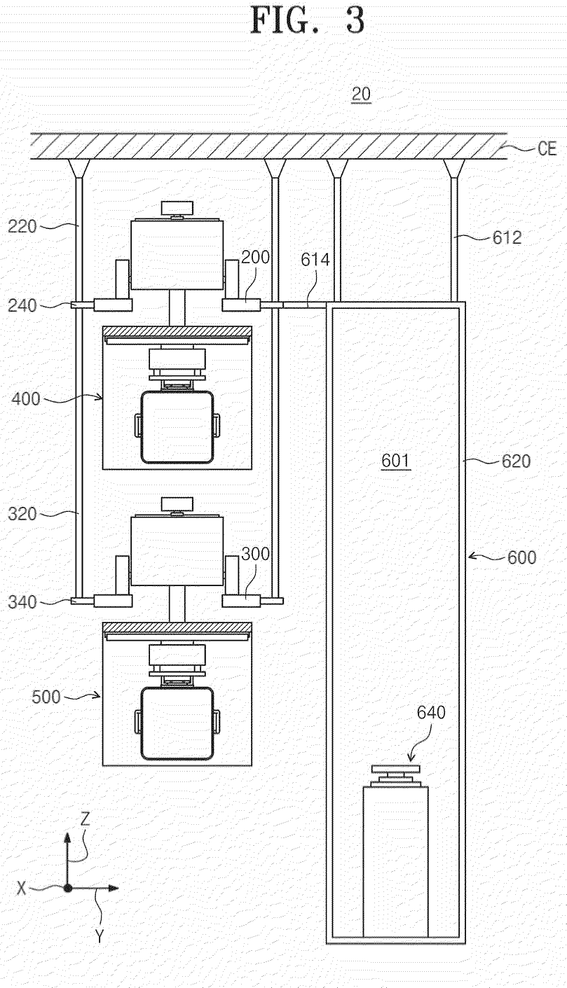

FIG. 3 is a diagram illustrating a transferring apparatus according to an embodiment of FIG. 1 when viewed from the front.

Referring to FIG. 3, the first rail 200 according to an embodiment of the present invention may be formed of a pair of rails. The pair of rails may be disposed to be spaced apart from each other. In addition, the pair of rails may be parallel to each other and disposed at the same height.

The first rail 200 may be fixed to a ceiling CE of the semiconductor manufacturing line. Specifically, the first rail 200 may be fixedly provided on the ceiling CE of the semiconductor manufacturing line via a first support 220 and a first fixture 240. According to an embodiment, the first support 220 may have a rod shape. The first support 220 may have a longitudinal direction horizontal to a third direction Z. One end of the first support 220 may be fixedly provided on the ceiling CE of the semiconductor manufacturing line. In addition, the other end of the first support 220 may be connected to the first fixture 240 connected to the first rail 200.

The second rail 300 according to an embodiment of the present invention may be formed of a pair of rails. The pair of rails may be disposed to be spaced apart from each other. In addition, the pair of rails may be parallel to each other and disposed at the same height.

The second rail 300 may be located below the first rail 200. The second rail 300 may be fixed to the ceiling CE of the semiconductor manufacturing line via the first rail 200. Specifically, one end of the second support 320 having a rod shape may be connected to the first fixture 240 connected to the first rail 200. In addition, the other end of the second support 320 may be connected to a second fixture 340 connected to the second rail 300. Accordingly, the second rail 300 may be connected with the first rail 200 and fixed to the ceiling CE of the semiconductor manufacturing line via the first rail 200.

However, it is not limited to the above-described example, and the first fixture 240 connected to the first rail 200 and the second fixture 340 connected to the second rail 300 are fixed to the ceiling CE of the semiconductor manufacturing line and may be connected to a support having a single rod shape, respectively.

The transfer unit 600 may be located at one side of the first rail 200 and the second rail 300. According to an embodiment, the transfer unit 600 may be located at the left or right side with respect to a longitudinal direction of the first rail 200. That is, the transfer unit 600 may be located at the left or right side with respect to the traveling direction of the first vehicle 400. In addition, the transfer unit 600 may be located at the left or right side with respect to the traveling direction of the second vehicle 500. The transfer unit 600 may be disposed at a position capable of transferring the container 12 from the first vehicle 400 traveling on the first rail 200.

The transfer unit 600 may be fixed to the ceiling CE of the semiconductor manufacturing line. For example, the transfer unit 600 may be fixed to the ceiling CE of the semiconductor manufacturing line by a frame support 612. For example, the frame support 612 may have a substantially rod shape. One end of the frame support 612 may be fixedly provided on the ceiling CE of the semiconductor manufacturing line, and the other end of the frame support 612 may be connected to an upper end of a frame 620 to be described below. For example, the other end of the frame support 612 may be connected to an upper wall 622 of the frame 620 to be described below.

In addition, the transfer unit 600 may be connected to a frame connector 614. For example, the frame connector 614 may be connected to a side wall frame 626 to be described below. The frame connector 614 may be connected to the first fixture 240 connected to the first rail 200. Accordingly, the transfer unit 600 may be connected to the first rail 200 via the frame connector 614. As described above, each of the first rail 200, the second rail 300, and the transfer unit 600 is fixedly provided on the ceiling CE of the semiconductor manufacturing line via the first support 220, the second support 320, and the frame support 612 in a longitudinal direction of the vertical direction. Accordingly, the first rail 200, the second rail 300, and the transfer unit 600 may be vulnerable to shaking in the first direction X and the second direction Y.

According to an embodiment of the present invention, the frame connector 614 connects the rails 200 and 300 and the transfer unit 600 to each other to prevent the rails 200 and 300 and the transfer unit 600 from shaking in a lateral direction. Accordingly, the structural stability of the rails 200 and 300 and the transfer unit 600 may be further improved.

The first vehicle 400 may exchange the container 12 with the transfer unit 600 to be described below. Specifically, the first vehicle 400 may unload the container 12 from an elevation plate 642 to be described below. In addition, the first vehicle 400 may load the container 12 seated on the elevation plate 642 to be described below.

The second vehicle 500 may exchange the container 12 with the semiconductor device 10 (see FIG. 1). For example, the second vehicle 500 may unload the container 12 from a load port (not illustrated) of the semiconductor device 10 or load the container 12 seated on the load port (not illustrated). In addition, the second vehicle 500 may exchange the container 12 with the transfer unit 600. For example, the second vehicle 500 may exchange the container 12 with the elevation plate 642 to be described below.

As described above, the first vehicle 400 exchanges the container 12 with the transfer unit 600 of the semiconductor device 10 and the transfer unit 600, and the second vehicle 500 may exchange the container 12 with the semiconductor device 10 and the transfer unit 600, respectively. That is, since the second vehicle 500 needs to exchange the container 12 with the semiconductor device 10, the second vehicle 500 may travel at a lower speed than that of the first vehicle 400. Unlike this, since the first vehicle 400 exchanges the container 12 with the transfer unit 600, unlike the second vehicle 500, the first vehicle 400 may travel at a high speed for the transfer efficiency of the container 12.

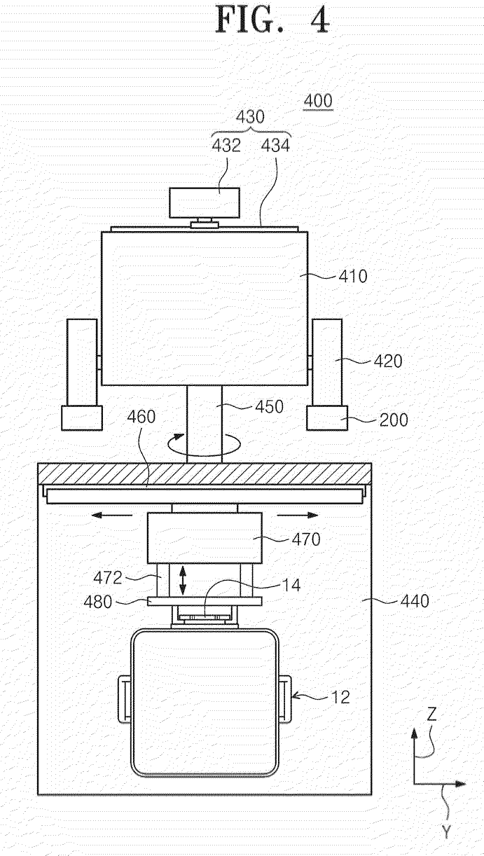

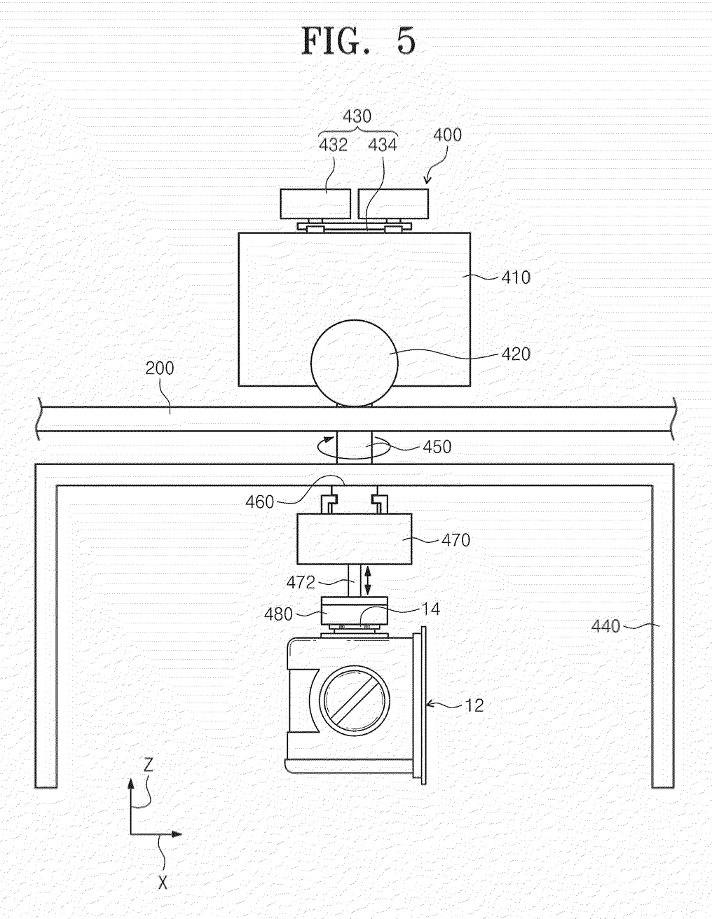

FIG. 4 is a diagram illustrating a state in which the first vehicle travels on the first rail according to an embodiment of FIG. 3 when viewed from the front. FIG. 5 is a diagram illustrating a state in which the first vehicle travels on the first rail according to an embodiment of FIG. 3 when viewed from the side.

Hereinafter, a vehicle according to an embodiment of the present invention will be described in detail with reference to FIGS. 3 to 5. Since the second vehicle has the same or similar structure as or to that of the first vehicle, hereinafter, for convenience of description, the first vehicle traveling on the first rail will be mainly described.

The first vehicle 400 travels on the first rail 200. The first vehicle 400 may hold the container 12. The first vehicle 400 may travel on the first rail 200 while holding the container 12. The first vehicle 400 may include a body 410, a traveling wheel 420, a steering part 430, a storage frame 440, a neck 450, a slider 460, an elevation part 470, and a holding part 480.

A traveling actuator (not illustrated) may be disposed inside the body 410. The traveling actuator (not illustrated) may rotate the traveling wheel 420. The traveling actuator (not illustrated) may transmit power to the traveling wheel 420 to rotate the traveling wheel 420. In addition, a plurality of bodies 410 may be provided. The traveling actuator (not illustrated) described above may be disposed inside each body 410. In addition, the traveling wheel 420, the steering part 430, and the neck 450 described above may be coupled to each body 410.

The traveling wheel 420 may be coupled to the body 410. The traveling wheel 420 may be rotatably coupled to the body 410. The traveling wheel 420 may rotate in contact with the first rail 200. A plurality of traveling wheels 420 may be provided. For example, the traveling wheels 420 may be formed in a pair. One of the traveling wheels 420 may be rotatably coupled to one surface of the body 410, and the other traveling wheel 420 may be rotatably coupled to the other surface facing one surface of the body 410.

The steering part 430 may be located above the body 410. The steering part 430 may include a plurality of steering wheels 432 and a steering rail 434. The plurality of steering wheels 432 may be disposed along a direction parallel to the traveling direction of the first vehicle 400 when viewed from the top.

When viewed from the top, the steering rail 434 may have a longitudinal direction parallel to a direction perpendicular to the traveling direction of the first vehicle 400. In addition, the positions of the steering wheels 432 may be changed along the longitudinal direction of the steering rail 434. The steering wheels 432 may be in contact with an upper rail (not illustrated) to change the traveling direction of the first vehicle 400. That is, while the positions of the steering wheels 432 are changed along the longitudinal direction of the steering rail 434, the steering wheels 432 may change a direction in contact with the upper rail (not illustrated), so that the traveling direction of the first vehicle 400 may be changed.

The storage frame 440 may have an internal space. The slider 460, the elevation part 470, and the holding part 480 may be located in the inner space of the storage frame 440. The storage frame 440 may have a substantially hexahedral shape. According to an embodiment, the storage frame 440 may have a structure in which the front and rear surfaces in a direction parallel to the traveling direction of the first vehicle 400 are blocked with a blocking plate. In addition, the storage frame 440 may have both side surfaces in contact with the front and rear surfaces thereof and an opened lower surface, respectively. Accordingly, it is possible to prevent the container 12 held by the first vehicle 400 from shaking due to air resistance when the first vehicle 400 is traveling.

The neck 450 may be coupled to the body 410. The neck 450 may be rotatably coupled to the body 410. In addition, the neck 450 may be coupled to an upper end of the storage frame 440. Accordingly, the storage frame 440 may be coupled to the body 410 via the neck 450. Although not illustrated, the storage frame 440 may be coupled to at least one body 410 via at least one neck 450. For example, two necks 450 may be coupled to one storage frame 440. In addition, the two necks 450 may be coupled to different bodies 410, respectively.

The slider 460 may be coupled to the storage frame 440. The slider 460 is located in the inner space of the storage frame 440 and may be coupled to a lower end of the upper surface of the storage frame 440. The slider 460 may be coupled to the storage frame 440 so that the position thereof may be changed. The slider 460 may be coupled to the storage frame 440 to change its position laterally (e.g., left and right direction) based on the traveling direction of the first vehicle 400. In addition, the slider 460 may be coupled to the elevation part 470 to be described below. Accordingly, when the position of the slider 460 is changed, the position of the elevation part 470 may also be changed.

The elevation part 470 may elevate the holding part 480 to be described below. The elevation part 470 may be coupled to the body 410 via the storage frame 440 and/or the neck 450. The elevation part 470 may have an actuator (not illustrated) therein. The actuator (not illustrated) may wind or unwind a belt 472 connected to the holding part 480 to elevate the holding part 480.

The holding part 480 may hold the container 12. For example, the holding part 480 may hold a flange 14 formed at an upper portion of the container 12. The holding part 480 may detachably hold the container 12. The holding part 480 may load the container 12 on the load port of the semiconductor device 10 (see FIG. 1) or unload the container 12 from the load port.

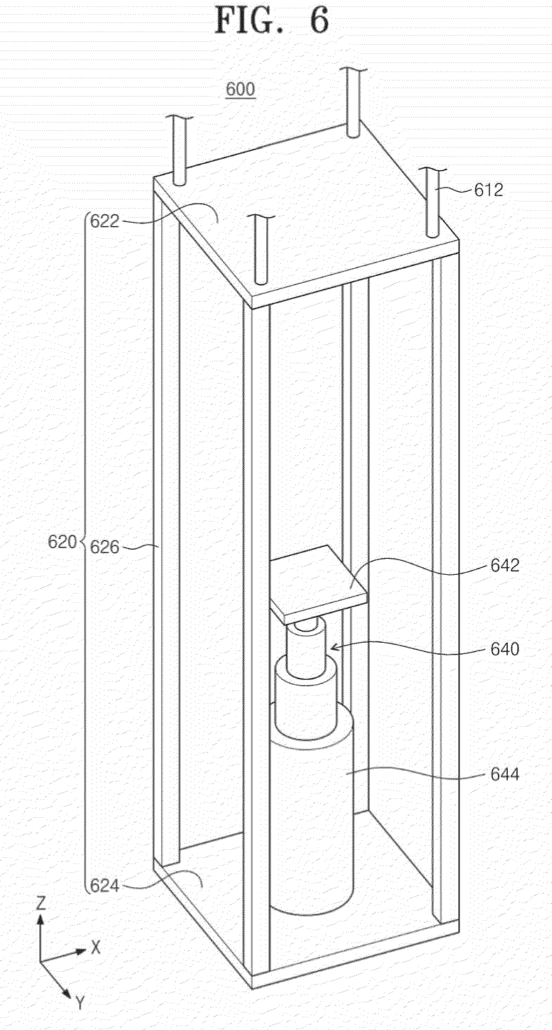

FIG. 6 is a perspective view of a transfer unit according to an embodiment of FIG. 3. Hereinafter, the transfer unit according to an embodiment of the present invention will be described in detail with reference to FIGS. 3 and 6.

Like the aforementioned contents, the transfer unit 600 transfers the container 12 between the first vehicle 400 and the second vehicle 500. According to an embodiment, the transfer unit 600 may transfer the container 12 while being transferred by the first vehicle 400 to the second vehicle 500. In addition, the transfer unit 600 may transfer the container 12 while being transferred by the second vehicle 500 to the first vehicle 400. In addition, the transfer unit 600 may temporarily store the container 12 transferred to the semiconductor device 10 (see FIG. 1) or transferred from semiconductor device 10.

The transfer unit 600 according to an embodiment may include a frame 620 and an elevation member 640.

The frame 620 has an elevation space 601 therein. The elevation space 601 may function as a space in which the container 12 is elevating. In addition, the elevation space 601 may function as a space in which the elevation member 640 to be described below moves. In addition, the elevation space 601 may function as a space in which the container 12 is temporarily stored.

According to an embodiment, the frame 620 may have a structure with an opened side. However, the present invention is not limited thereto, and the frame 620 may have a structure with an opened side. For example, only one side of the frame 620 facing the first rail 200 and the second rail 300 may be opened. The container 12 may be transferred between the first vehicle 400, the second vehicle 500, and the elevation plate 642 to be described below through the opened side. Hereinafter, for convenience of understanding, a case in which both sides of the frame 620 have an open structure will be described as an example.

The frame 620 may include an upper wall 622, a lower wall 624, and a side wall frame 626. The upper wall 622 and the lower wall 624 may be plates having a substantially rectangular shape. The upper wall 622 may be connected to the frame support 612 connected to the ceiling of the semiconductor manufacturing line. In addition, a side end of the upper wall 622 may be connected to the frame connector 614. The elevation member 640 to be described below may be disposed on the upper surface of the lower wall 624. The lower wall 624 may be located below the container 12 held by the second vehicle 500 when viewed from the front.

The side wall frame 626 may have a longitudinal direction in the vertical direction. A plurality of side wall frames 626 may be provided. The side wall frames 626 may be coupled to corners of the upper wall 622 and the lower wall 624, respectively. For example, four side wall frames 626 are provided, one end of each side wall frame 626 may be coupled with the corners of the upper wall 622, respectively, and the other end of each side wall frame 626 may be coupled with the corners of the lower wall 624, respectively.

The elevation member 640 is located in the elevation space 601. The elevation member 640 elevates the container 12 in the elevation space 601. That is, the elevation member 640 moves the container 12 in a vertical direction. The elevation member 640 elevates the container 12 between a first position and a second position in the elevation space 601. The first position is defined as a position where the first vehicle 400 traveling on the first rail 200 and the elevation plate 642 to be described below transfer the container. For example, when the slider 460 of the first vehicle 400 slides to move the container 12 into the elevation space 601, the elevation plate 642 may be located at the first position which is the lower side of the container 12. In addition, the second position is defined as a position where the second vehicle 500 traveling on the second rail 300 and the elevation plate 642 transfers the container. For example, when the slider 560 of the second vehicle 500 slides to move the container 12 into the elevation space 601, the elevation plate 642 may be located at the second position which is the lower side of the container 12.

The elevation member 640 may include the elevation plate 642 and the driving member 644. The elevation plate 642 may support the container 12. For example, the elevation plate 642 may support the lower surface of the container 12. In FIG. 6, the elevation plate 642 is illustrated to have a rectangular shape, but is not limited thereto. The elevation plate 642 may have various shapes, such as a circular shape and a polygonal shape. Although not illustrated, a rubber ring-shaped anti-slip member may be provided on the upper surface of the elevation plate 642 to prevent the container 12 from sliding.

The driving member 644 is located in the elevation space 601. The driving member 644 may be provided on the lower wall 624 of the frame 620. In addition, the driving member 644 is coupled to the elevation plate 642. For example, the driving member 644 may be coupled to a lower end of the elevation plate 642. The driving member 644 elevates the elevation plate 642. That is, the driving member 644 moves the elevation plate 642 in the third direction Z. According to an embodiment, the driving member 644 may be a cylinder motor having a multi-stage structure. However, the present invention is not limited thereto, and the driving member 644 may be modified into various devices capable of transmitting the driving force to the elevation plate 642.

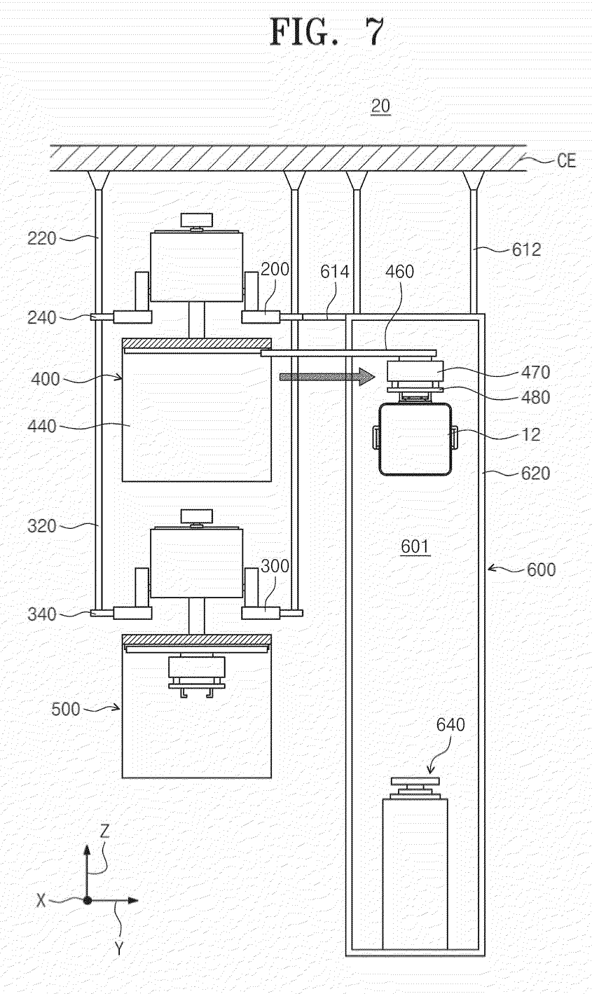

FIGS. 7 to 11 are diagrams sequentially illustrating a state of exchanging a container in the transferring apparatus according to the embodiment of FIG. 3. Hereinafter, a transferring method according to an embodiment of the present invention will be described in detail with reference to FIGS. 7 to 11.

Referring to FIG. 7, the first vehicle 400 may move the transferring container 12 to the elevation space 601. Specifically, the slider 460 provided in the first vehicle 400 slides in the direction (e.g., the second direction Y) toward the frame 620 to move the container 12 to the elevation space 601. The slider 460 moves to a first position, which is a position at which the container 12 may be transferred to the elevation plate 642.

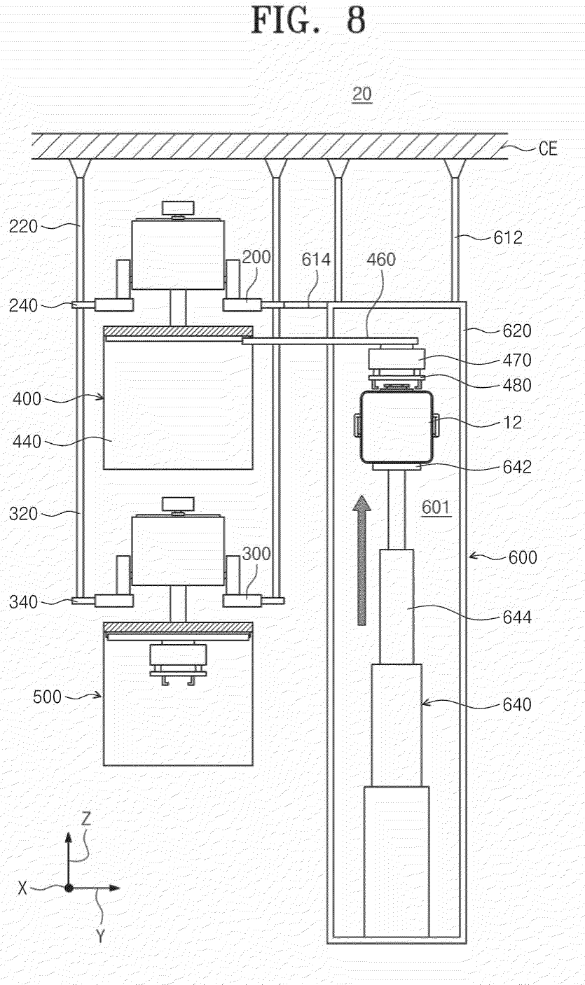

Referring to FIG. 8, the driving member 644 elevates the elevation plate 642 to the first position. For example, when the elevation plate 642 is positioned below the first position, the driving member 644 moves the elevation plate 642 to the first position in an upper direction (e.g., the third direction Z). When both the elevation plate 642 and the slider 460 are positioned at the first position, the holding part 480 transfers the holding container 12 to the elevation plate 642. The elevation plate 642 receives the container 12. Accordingly, the container 12 is seated and supported on the upper surface of the elevation plate 642.

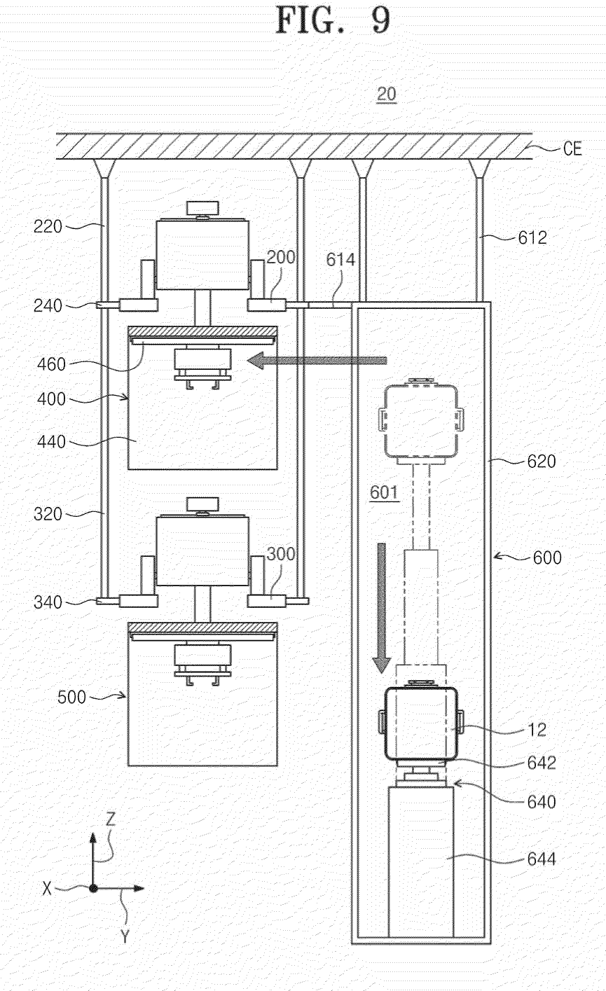

Referring to FIG. 9, the driving member 644 lowers the elevation plate 642 downward to move the elevation plate 642 to the second position. When the elevation plate 642 is located at the second position, the driving member 644 stops the movement of the elevation plate 642.

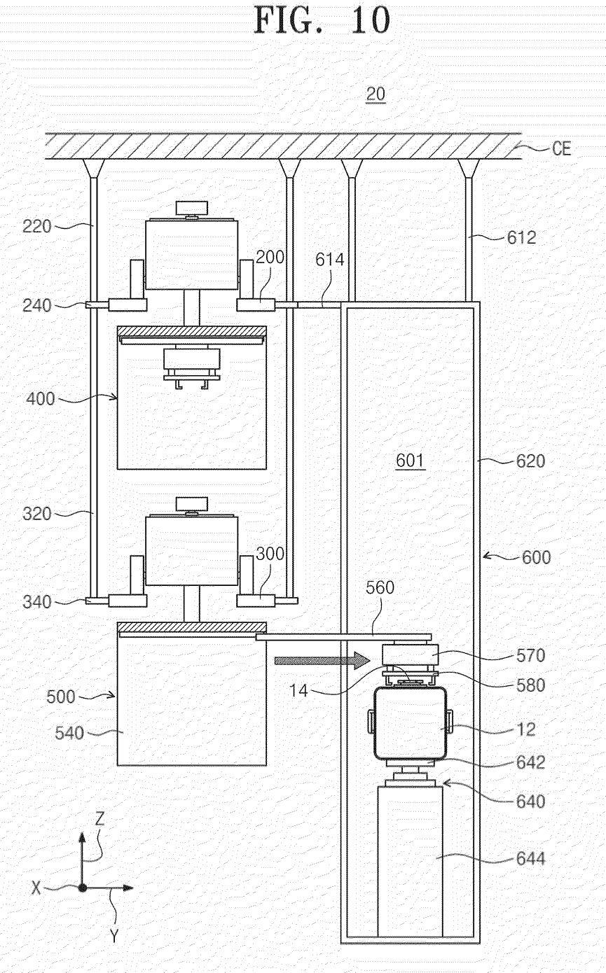

Referring to FIG. 10, when the elevation plate 642 supporting the container 12 is located at the second position, the slider 560 provided in the first vehicle 400 moves to the second position, which is a position at which the container 12 supported by the elevation plate 642 may be received. For example, the slider 560 slides in a direction (e.g., the second direction Y) toward the frame 620. When the slider 560 is located at the first position, the holding part 480 holds the flange 14 formed above the container 12 supported by the elevation plate 642. Accordingly, the container 12 is transferred from the elevation plate 642 to the first vehicle 400.

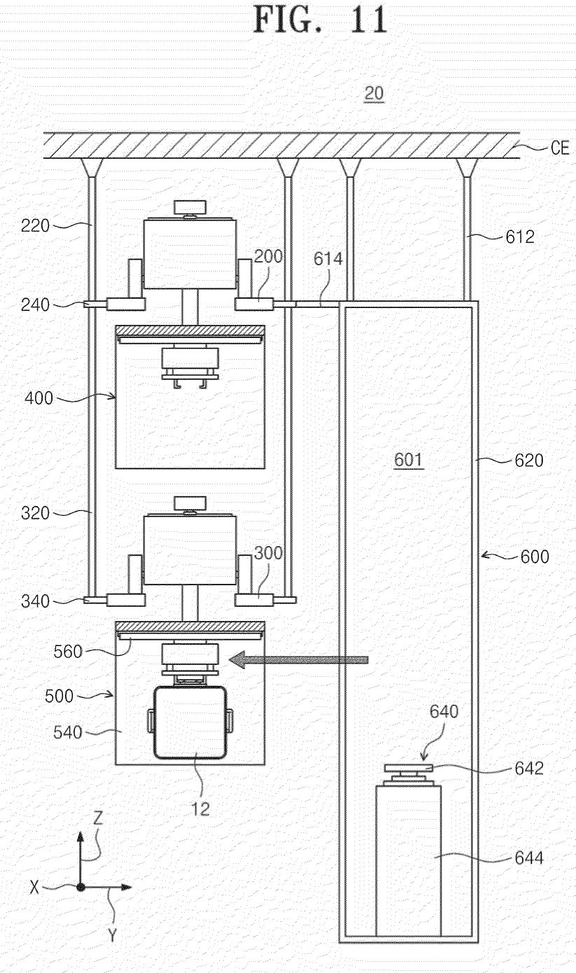

Referring to FIG. 11, the slider 560 moves the received container 12 into the storage frame 440. When the container 12 is located inside the storage frame 540 of the second vehicle 500, the second vehicle 500 may travel along the second rail 300.

According to an embodiment of the present invention described above, it is possible to efficiently exchange the container 12 between the vehicles 400 and 500 traveling on the rails 200 and 300 disposed at different heights. That is, it is possible to more efficiently exchange the container 12 between the vehicles 400 and 500 traveling at different speeds via the transfer unit 600.

In addition, in order to exchange the container 12 between the vehicles 400 and 500 traveling on the different rails 200 and 300 at different speeds, it is unnecessary to provide a separate rail (e.g., slope rail) connecting the different rails 200 and 300. Accordingly, it is possible to minimize structural complexity within a semiconductor manufacturing line space.

In the above-described embodiment, the mechanism in which the elevation plate 642 moves the container 12 from the first position to the second position has been described as an example, but is not limited thereto. For example, even when the second vehicle 500 transfers the transferring container 12 to the first vehicle 400, the transferring may be performed by the same or similar mechanism as or to the above-described example.

For example, the second vehicle 500 may move the transferring container 12 to the elevation space 601. For example, the slider 560 provided on the second vehicle 500 moves to a second position, which is a position at which the container 12 may be transferred to the elevation plate 642. The driving member 644 locates the elevation plate 642 at the second position, and the elevation plate 642 receives the container 12 from the slider 560. The elevation plate 642 elevates from the second position to the first position, and a slide driver 662 slidably moves the support plate 664 from a stand-by position to a support position. When the support plate 664 supports the container 12, the slider 460 provided on the first vehicle 400 moves to the first position and receives the container 12. The slider 460 moves the container 12 into the storage frame 440 of the first vehicle 400.

Hereinafter, a transfer unit according to another embodiment of the present invention will be described. A transfer unit according to an embodiment of the present invention to be described below is substantially the same as or similar to the configuration of the transfer unit according to the embodiment of the present invention described above, except for configurations to be further described.

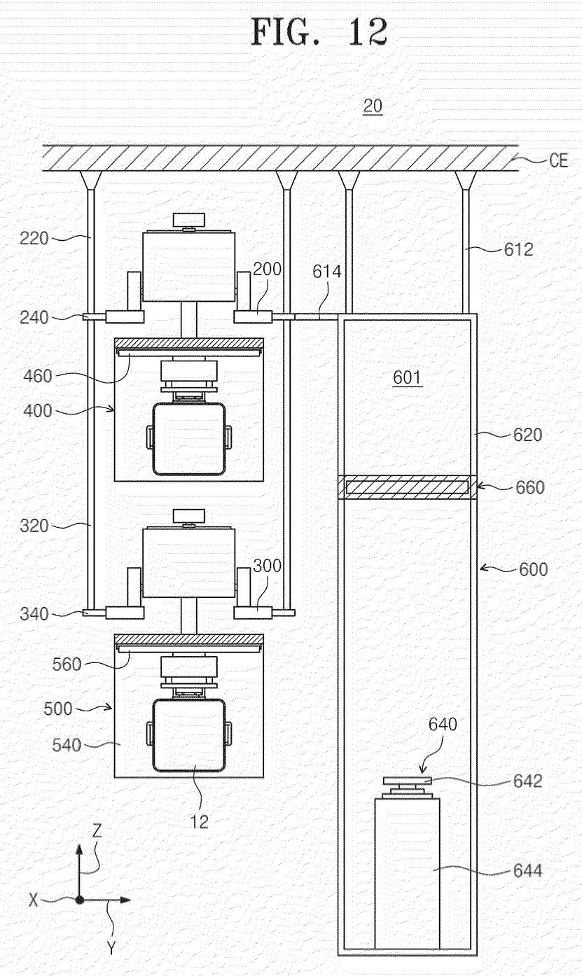

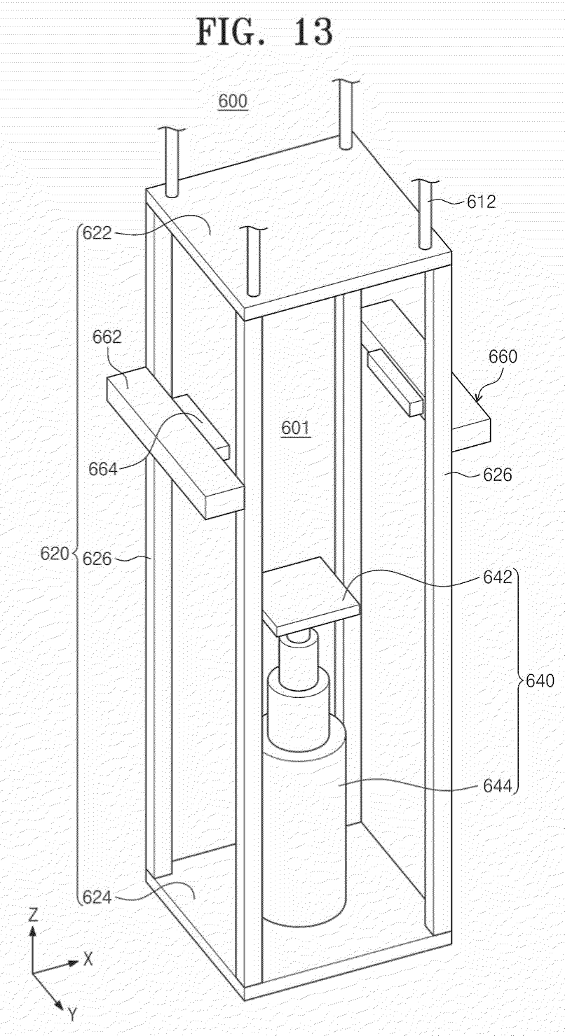

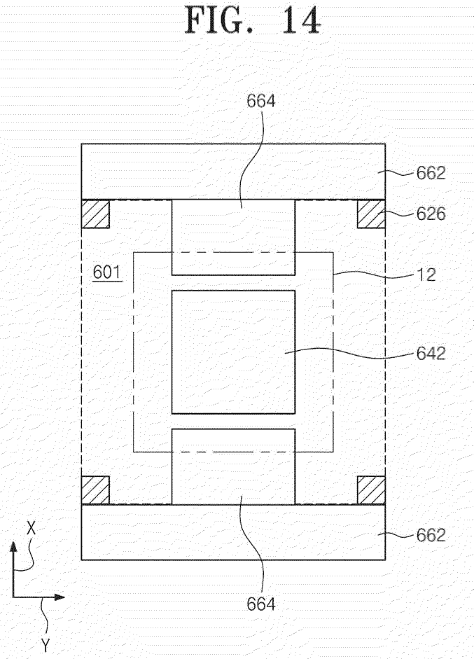

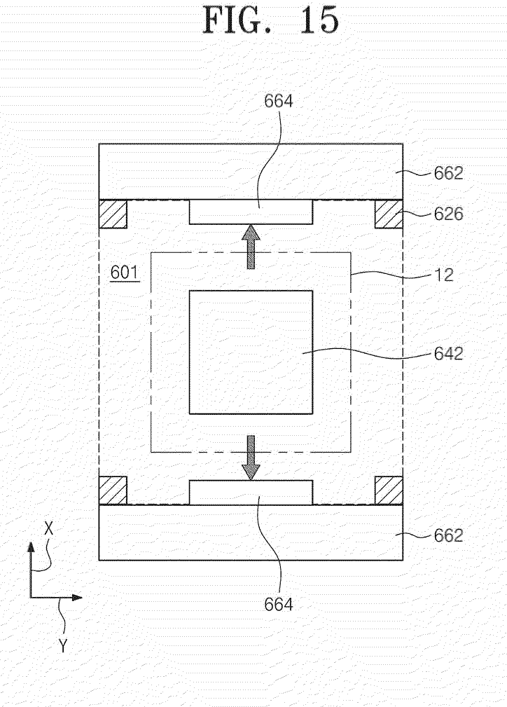

FIG. 12 is a diagram illustrating a transfer unit according to another embodiment of FIG. 3 when viewed from the front. FIG. 13 is a perspective view of the transfer unit according to another embodiment of FIG. 12. FIG. 14 is a diagram schematically illustrating the transfer unit when viewed from the top, when a support plate of FIG. 12 is located at a support position. FIG. 15 is a diagram schematically illustrating the transfer unit when viewed from the top, when the support plate of FIG. 12 is located at a stand-by position.

Referring to FIGS. 12 and 13, a transfer unit 600 may include a frame 620, an elevation member 640, and a support member 660. Descriptions of the aforementioned frame 620 and the elevation member 640 will be omitted.

The support member 660 may be provided on the frame 620. The support member 660 may support the container 12 in the elevation space 601. In addition, the support member 660 may transfer the container 12 in the elevation space 601. For example, the support member 660 may transfer the first vehicle 400 and the container 12. In addition, the support member 660 may transfer the elevation member 640 and the container 12.

The support member 660 may include the support plate 664 and the slide driver 662.

The slide driver 662 is provided on the frame 620. According to an embodiment, the slide driver 662 may be provided on the side wall frame 626. The slide driver 662 slidably moves the support plate 664 to be described below. A slit, which is a space in which the support plate 664 slides, may be formed in the slide driver 662. For example, the slide driver 662 may be a motor. However, the present invention is not limited thereto, and the slide driver 662 may be modified into various known devices capable of slidably moving the support plate 664.

Hereinafter, the support plate according to an embodiment of the present invention will be described with reference to FIGS. 12 to 15.

The support plate 664 may be provided at the first position. The support plate 664 supports the container 12 at the first position. For example, the support plate 664 may be provided at a position corresponding to the position of the elevation plate 642 when the elevation plate 642 is located at the first position to transfer the slider 460 and the container 12 (see FIG. 8). That is, when the elevation plate 642 is located at the first position, the upper surface of the support plate 664 may be located at a height corresponding to the upper surface of the elevation plate 642.

In addition, the support plate 664 may slide between a support position and a stand-by position. Specifically, the support plate 664 may slide between the support position and the stand-by position through the slit formed in the slide driver 662.

The support position may be defined as a position at which the support plate 664 may support the container 12 within the elevation space 601. For example, as illustrated in FIG. 14, when the support plate 664 slides to be located at the support position, a partial region of the support plate 664 may overlap with a partial region of the container 12 seated and supported on the elevation plate 642. In addition, when the support plate 664 is located at the support position, the support plate 664 may not overlap with the elevation plate 642. That is, when the support plate 664 is located at the support position, the support plate 664 may not interfere with the elevation plate 642 that elevates the elevation space 601.

The stand-by position may be defined as a position at which the support plate 664 does not support the container 12 inside the elevation space 601. In addition, the stand-by position may be defined as a position at which the support plate 664 does not interfere with the container 12 elevating inside the elevation space 601. For example, as illustrated in FIG. 15, when the support plate 664 slides to be located at the stand-by position, the entire region of the support plate 664 may not overlap with the container 12 located in the elevation plate 601. That is, when the support plate 664 is located at the stand-by position, the support plate 664 may not interfere with the container 12 moving up and down inside the elevation space 601.

In addition, the support plate 664 may be a plate having a substantially quadrangular shape when viewed from the top. This is just for illustrative of the example, and the support plate 664 may have various shapes. In addition, when the support plate 664 is located at the support position, the support plate 664 may have a shape not overlapping with the elevation plate 642.

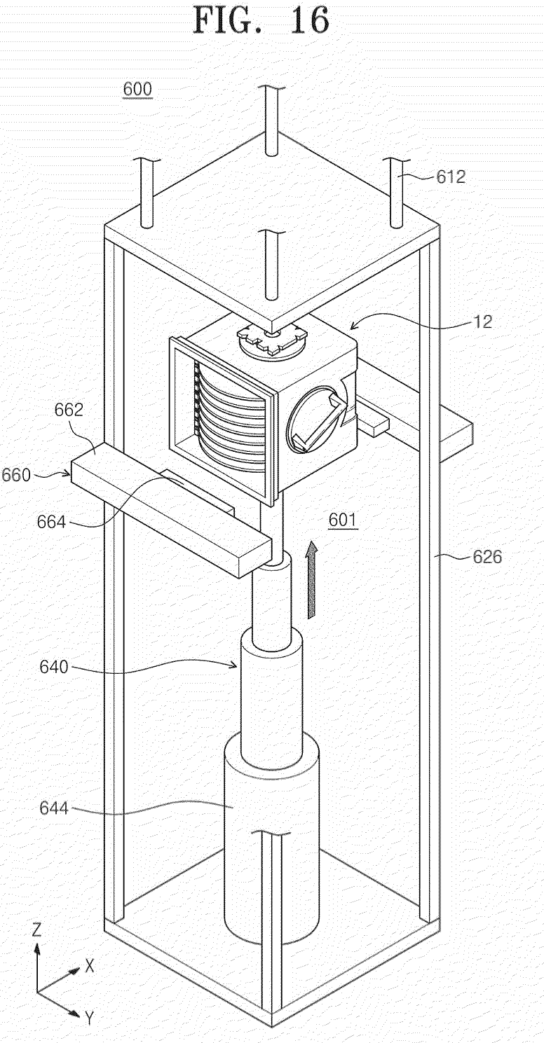

FIGS. 16 to 18 are diagrams sequentially illustrating a state in which the container is transferred in the elevation space of the transfer unit according to an embodiment of FIG. 12. Hereinafter, a mechanism in which the container is transferred in the elevation space of the transfer unit according to an embodiment of the present invention will be described in detail with reference to FIGS. 16 to 18.

Referring to FIG. 16, the elevation member 640 may receive the container 12 at the second position. For example, the elevation plate 642 may receive the container 12 at the second position from the second vehicle 500 (see FIG. 12). The elevation plate 642 may elevate the container 12 to the first position. When the elevation plate 642 elevates the container 12, the support plate 664 is located at the stand-by position. Accordingly, each of the elevation plate 642 and the container 12 supported by the elevation plate 642 may elevate from the second position to the first position without interfering with the support plate 664.

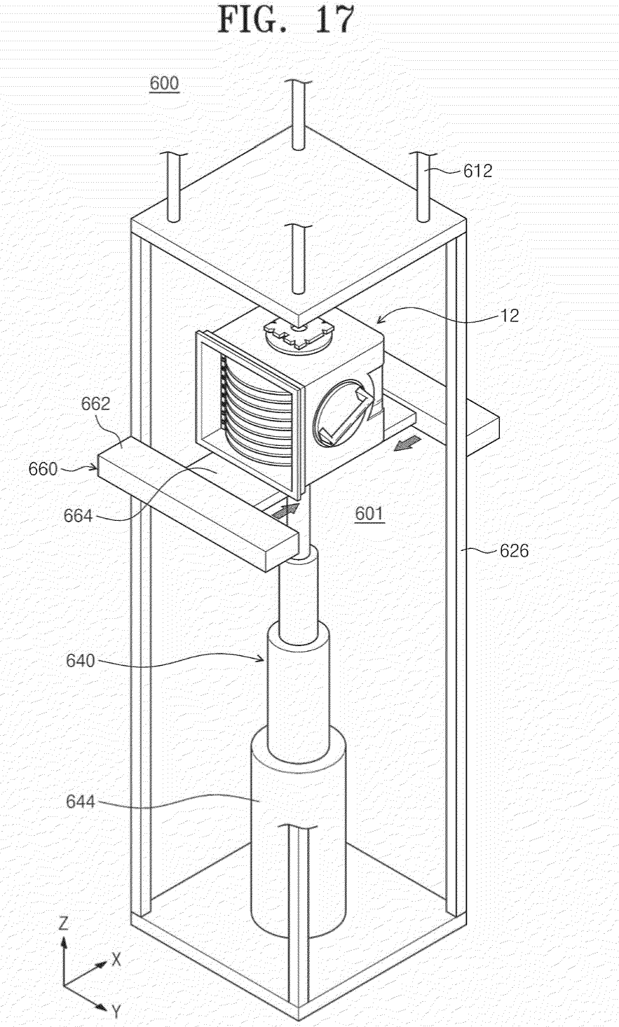

As illustrated in FIG. 17, when the elevation member 640 moves to the first position, the slide driver 662 slidably moves the support plate 664 from the stand-by position to the support position. The support plate 664 located at the support position may be seated on the elevation plate 642 to support a lower surface of the supported container 12.

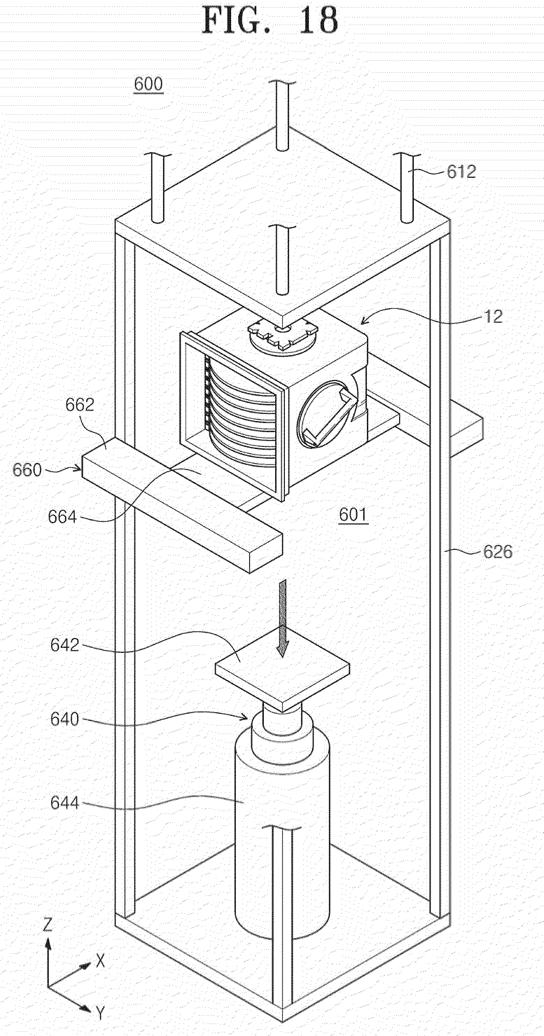

As illustrated in FIG. 18, after the support plate 664 is located at the support position to support the container 12, the elevation plate 642 may descend from the first position to the second position. In this case, since the container 12 is supported by the support plate 664, only the elevation plate 642 may descend to the second position. The container 12 supported by the support plate 664 is transferred to the first vehicle 400 (see FIG. 12). Simultaneously, the elevation plate 642 descending to the second position may receive the container 12 from the second vehicle 500 (see FIG. 12).

According to the embodiment of the present invention described above, the transfer of the container 12 from the second vehicle 500 (see FIG. 12) to the first vehicle 400 (see FIG. 12) may be performed efficiently. That is, instead of directly transferring the container 12 between the elevation plate 642 and the first vehicle 400, the container 12 is transferred by the transfer unit 600, thereby more effectively saving the time when the container 12 is transferred between the elevation plate 642 and the first vehicle 400. Accordingly, the elevation plate 642 may more quickly transfer the container 12 transferred by the subsequent second vehicle 500 to the subsequent first vehicle 400.

Hereinafter, a transferring apparatus according to another embodiment of the present invention will be described. Since a transferring apparatus to be described below is substantially the same as or similar to the transferring apparatus according to the embodiment described above, descriptions of duplicated contents will be omitted. In addition, the duplicated configurations designate the same reference numerals as those of the transferring apparatus according to the embodiment described above, and non-duplicated configurations designate different same reference numerals.

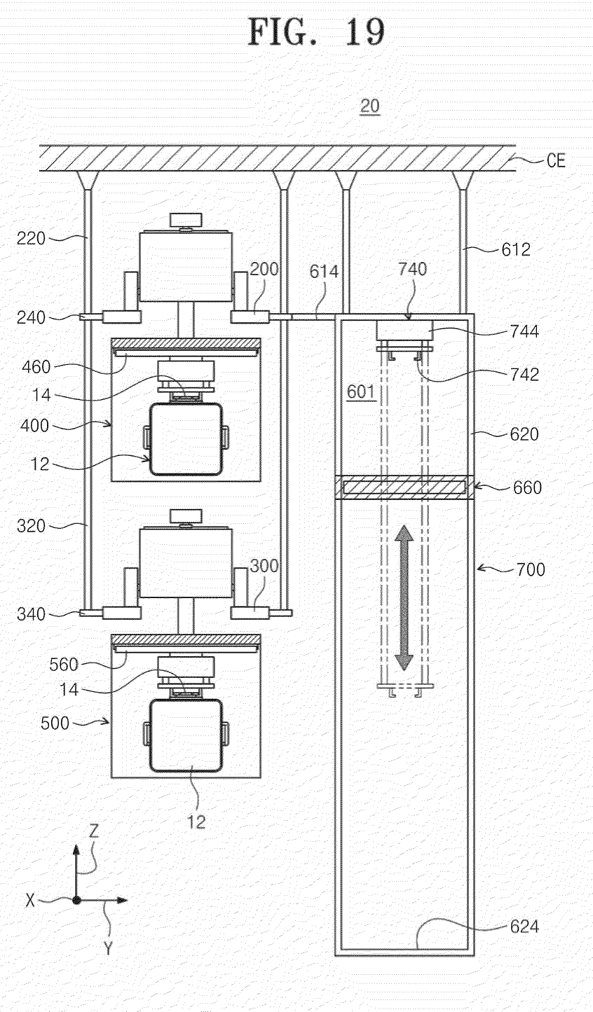

FIG. 19 is a diagram illustrating a transfer unit according to another embodiment of FIG. 12 when viewed from the front.

Referring to FIG. 19, a transfer unit 700 according to the embodiment of the present invention may include a frame 620, an elevation member 740, and a support member 660.

The frame 620 and the support member 660 according to an embodiment of the present invention are provided substantially the same as or similar to the frame 620 described above.

However, when viewed from the front, a lower wall 624 of the frame 620 according to an embodiment of the present invention is preferably located at a height corresponding to the container 12 which is being transferred by the second vehicle 500. However, the present invention is not limited thereto, and as illustrated in FIG. 19, it is sufficient if the lower wall 624 of the frame 620 is located lower than the container 12 which is being transferred by the second vehicle 500.

The elevation member 740 elevates the container 12 in the elevation space 601. The elevation member 740 moves the container 12 in a vertical direction in the elevation space 601. The elevation member 740 elevates the container 12 between a first position and a second position in the elevation space 601.

The first position is defined as a position where the first vehicle 400 traveling on the first rail 200 and the elevation plate 740 transfer the container 12 via the support plate 664. For example, when the slider 460 of the first vehicle 400 slides to move the container 12 into the elevation space 601, the support plate 664 may be located at the support position. When the support plate 664 supports the container 12 at the support position, a grip member 742 to be described below may be located at the first position, which is a position for gripping the flange 14 formed at the upper portion of the container 12.

The second position is defined as a position where the second vehicle 500 traveling on the second rail 300 and the elevation member 740 transfer the container 12. For example, the second position may be defined as a position where the grip member 742 seats the container 12 on the lower wall 624 of the frame 620. When the grip member 742 seats the container 12 on the lower wall 624, the slider 560 of the second vehicle 500 may move to the second position to receive the container 12.

The elevation member 740 may include the grip member 742 and a driving member 744.

The grip member 742 is located in the elevation space 601. The grip member 742 elevates inside the elevation space 601 by the driving member 744 to be described below. The grip member 742 may elevate between the first position and the second position. The grip member 742 may grip the flange 14 formed at the upper portion of the container 12 located in the elevation space 601.

The driving member 744 may elevate the grip member 742. The driving member 744 may elevate the grip member 742 between the first position and the second position. The driving member 744 may be provided on the frame 620. For example, the driving member 744 may be provided on an upper wall 622 of the frame 620. According to an embodiment, the driving member 744 may be a hoist device consisting of a wire and a motor. For example, when the wire is wound around the motor and the motor rotates forward, the grip member 742 moves downward, and when the motor rotates backward, the grip member 742 may move upward. However, this is only illustrated for convenience of understanding.

According to an embodiment of the present invention, the slider 460 provided on the first vehicle 400 may move the transferring container 12 to the elevation space 601. For example, the slider 460 may move container 12 to the first position. While or before the slider 460 moves the container 12 to the first position, the slide driver 662 slidably moves the support plate 664 to the support position. When the slider 460 is located at the first position and the support plate 664 is located at the support position, the slider 460 transfers the container 12 to the support plate 664. The support plate 664 supports a lower surface of the container 12. When the container 12 is seated on the support plate 664, the slider 460 moves out of the elevation space 601 again.

Thereafter, the driving member 744 elevates the grip member 742 to the first position, and the grip member 742 grips the flange 14 formed at the upper portion of the container 12 seated on the support plate 664 at the first position. When the grip member 742 grips the flange 14, the support plate 664 slides from the support position to the stand-by position. When the support plate 664 is located at the stand-by position, the driving member 744 lowers the grip member 742 from the first position to the second position. When the grip member 742 is located at the second position, the grip member 742 releases the container 12, and the container 12 is seated on the lower wall 624 of the frame 620. The slider 560 provided in the second vehicle 500 moves to the second position to receive the container 12. Such a mechanism is performed in the same or similar manner even when the container 12 is transferred from the second vehicle 500 to the first vehicle 400.

In the embodiment of the present invention described above, it has been described as an example that the support member 660 is provided at the first position, but is not limited thereto. For example, the support member 660 may be provided at the first position and/or the second position. In addition, unlike the above example, the elevation plate 642 or the grip member 742 may elevate inside the elevation space 601 by a belt drive type driving member having a pulley.

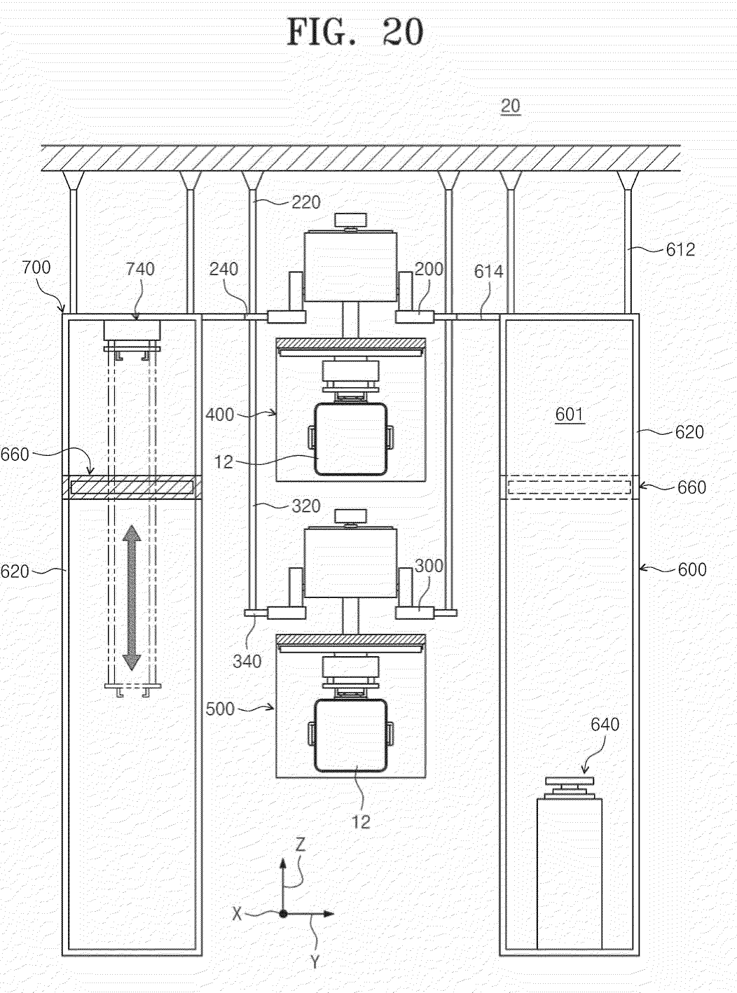

FIG. 20 is a diagram illustrating a transfer unit according to another embodiment of FIG. 12 when viewed from the front.

Referring to FIG. 20, the transfer unit may include a first transfer unit 600 and a second transfer unit 700.

The first transfer unit 600 according to an embodiment of the present invention may include a frame 620, a first elevation member 640, and a support member 660. The first transfer unit 600 according to the embodiment of the present invention is the same as or similar to the transfer unit 600 described with reference to FIGS. 12 to 18. In particular, the first elevation member 640 according to an embodiment of the present invention has the same or similar configuration as the elevation member 640 described with reference to FIGS. 12 to 18.

The second transfer unit 700 according to an embodiment of the present invention may include a frame 620, a second elevation member 740, and a support member 660. The second transfer unit 700 according to the embodiment of the present invention is the same as or similar to the transfer unit 700 described with reference to FIG. 19. In particular, the second elevation member 740 is the same as or similar to the elevation member 740 according to an embodiment of the present invention.

The first transfer unit 600 is located on one side of the first rail 200 based on the first rail 200. For example, as illustrated in FIG. 20, when viewed from the front, the first transfer unit 600 may be located on the right side of the first rail 200. In addition, the second transfer unit 700 may be located to face the first transfer unit 600 based on the first rail 200. For example, as illustrated in FIG. 20, when viewed from the front, the second transfer unit 700 may be located on the left side of the first rail 200. Among side surfaces of the frame 620 of the first transfer unit 600, the side surface facing the first rail 200 is opened. In addition, among side surfaces of the frame 620 of the second transfer unit 700, the side surface facing the first rail 200 is opened.

Each of the first transfer unit 600 and the second transfer unit 700 may elevate the container 12 inside the elevation space 601. For example, each of the first transfer unit 600 and the second transfer unit 700 may elevate the container 12 between the first position and the second position. Optionally, the first transfer unit 600 may elevate the container 12 from the second position to the first position, and the second transfer unit 700 may elevate the container 12 from the first position to the second position. That is, the first transfer unit 600 may transfer the container 12 only from the second vehicle 500 to the first vehicle 400. In addition, the second transfer unit 700 may transfer the container 12 only from the first vehicle 400 to the second vehicle 500. Alternatively, the first transfer unit 600 may transfer the container 12 only from the second vehicle 500 to the first vehicle 400, and the second transfer unit 700 may transfer the container 12 only from the first vehicle 400 to the second vehicle 500. Each of the transfer units 600 and 700 transfers the container 12 in only one direction, thereby more effectively transferring the container 12.

In addition, a plurality of first transfer units 600 may be disposed along the longitudinal directions of the first rail 200 and the second rail 300. In addition, a plurality of second transfer units 700 may be disposed along the longitudinal directions of the first rail 200 and the second rail 300.

In the above example, it has been described as an example that the transfer device 20 is applied to the semiconductor manufacturing line 1, but is not limited thereto. For example, the transfer device 20 may be applied in the same or similar manner as or to various manufacturing lines requiring transferring of articles.

The foregoing detailed description illustrates the present invention. Further, the above content shows and describes the embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing embodiment describes the best state for implementing the technical spirit of the present invention, and various changes required in specific application fields and uses of the present invention are possible. Accordingly, the detailed description of the invention above is not intended to limit the invention to the disclosed embodiment. Further, the accompanying claims should be construed to include other embodiments as well.

1. A transferring apparatus for transferring a container in which an article is accommodated, comprising:
a first rail;
a second rail located below the first rail; and
a transfer unit located on the sides of the first rail and the second rail to transfer the container between a first vehicle traveling on the first rail and a second vehicle traveling on the second rail,
wherein the transfer unit comprises
a frame having an elevation space therein; and
an elevation member for elevating the container between a first position transferring the first vehicle and the container and a second position transferring the second vehicle and the container, in the elevation space.

2. The transferring apparatus of claim 1, wherein
the transferring apparatus is disposed above a plurality of semiconductor devices,
a semiconductor manufacturing line in which the plurality of the semiconductor devices are continuously disposed is formed of at least one floor, and
the first rail, the second rail, and the transfer unit are disposed on the same layer of the semiconductor manufacturing line.

3. The transferring apparatus of claim 2, wherein
the second vehicle travels on the second rail at a speed lower than that of the first vehicle to transfer the semiconductor device and the container.

4. The transferring apparatus of claim 2, wherein
the first rail and the frame are fixed to a ceiling of the semiconductor manufacturing line, and
the second rail is fixed via the first rail.

5. The transferring apparatus of claim 1, wherein the transfer unit comprises
a first transfer unit located on one side of the first rail; and
a second transfer unit located on the other side facing one side of the first rail based on the first rail.

6. The transferring apparatus of claim 5, wherein
the first transfer unit includes a first frame and a first elevation member,
wherein the first elevation member comprises
an elevation plate for supporting a lower surface of the container; and
a first driving member provided on a lower wall of the first frame and moving the elevation plate in a vertical direction,
the second transfer unit includes a second frame and a second elevation member,
wherein the second elevation member comprises
a grip member for gripping a flange formed at an upper portion of the container; and
a second driving member provided on an upper wall of the second frame and moving the grip member in a vertical direction.

7. The transferring apparatus of claim 1, wherein
the first vehicle travels only on the first rail of the first rail and the second rail, and the second vehicle travels only on the second rail of the first rail and the second rail.

8. The transferring apparatus of claim 1, wherein
the transfer unit further comprises
a support member for transferring the first vehicle, the elevation member, and the container in the elevation space.

9. The transferring apparatus of claim 8, wherein
the support member is provided at the first position.

10. The transferring apparatus of claim 9, wherein
the support member is provided on the frame and slides between a support position capable of supporting the container in the elevation space and a stand-by position which does not interfere with the container elevating in the elevation space.

11. The transferring apparatus of claim 10, wherein
the support member does not interfere with the elevation member when the elevation member moves up and down in the elevation space.

12. The transferring apparatus of claim 11, wherein
each of the first vehicle and the second vehicle comprises a slider that changes the position of the container laterally with respect to a traveling direction,
among side surfaces of the frame, the side surfaces facing the first rail and the second rail are opened, and
the slider moves the container to the elevation space through the opened side surfaces.

13. The transferring apparatus of claim 12, further comprising:
a controller,
wherein the controller is configured to control the support member, the slider, and the elevation member so as to
seat the container on the support member by moving the slider to the elevation space after slidably moving the support member to the support position when moving the container from the first vehicle to the elevation space, to elevate the elevation member to the first position so that the elevation member supports the container after the container is seated on the support member, and to slidably move the support member to the stand-by position after the elevation member supports the container.

14. The transferring apparatus of claim 12, further comprising a controller,
wherein the controller is configured to control the support member, the slider, and the elevation member so that
the elevation member slidably moves the support member to the stand-by position before elevating the container to the first position when moving the container to the first vehicle in the elevation space, the elevation member elevates the container to the first position when the support member moves to the stand-by position, and the elevation member slidably moves the support member to the support position when the elevation member is located at the first position.

15-19. (canceled)

20. A transferring apparatus for transferring a container in which an article is accommodated in the same layer of a semiconductor manufacturing line in which semiconductor devices are continuously disposed, the transferring apparatus comprising:
a first vehicle traveling on a fist rail to transfer the container;
a second vehicle traveling on a second rail located below the first rail to transfer the container; and
a plurality of transfer units located sides of the first rail and the second rail to transfer the container between the first vehicle and the second vehicle,
wherein the first vehicle includes a first slider for changing the position of the container while being transferring by the first vehicle laterally with respect to the traveling direction of the first vehicle, and
the second vehicle includes a second slider for changing the position of the container while being transferring by the second vehicle laterally with respect to the traveling direction of the second vehicle, and
wherein the transfer unit comprises
a frame having an elevation space therein; and
an elevation member for elevating the container between a first position transferring the first vehicle and the container and a second position transferring the second vehicle and the container.
